(19) United States
(12) Patent Application Publication
(10) Pub. No.: US 2016/0219704 A1
(43) Pub. Date: Jul. 28, 2016

(54) HERMETICALLY SEALED THROUGH VIAS (TVS)

(71) Applicant: RF Micro Devices, Inc., Greensboro, NC (US)

(72) Inventors: Jan Edward Vandemeer, Kernersville, NC (US); Khoi Tam Vu, Jamestown, NC (US)

(21) Appl. No.: 15/008,691

(22) Filed: Jan. 28, 2016

Related U.S. Application Data
(60) Provisional application No. 62/109,018, filed on Jan. 28, 2015.

(51) Int. Cl. H05K 1/11; H01L 21/768; H05K 3/46; H05K 1/03; H05K 1/02; H01L 23/538; H01L 21/56

(52) U.S. Cl. CPC H05K 1/115; H01L 23/5384; H01L 23/5386; H01L 21/76879; H01L 21/563; H05K 1/0306; H05K 1/0298; H05K 3/4647

(57) ABSTRACT

Hermetically sealed through vias (TVs) are disclosed. In one aspect, an hourglass TV is first created in a substrate. The hourglass TV has a waist opening. A conductive conformal coating covers at least a portion of an interior wall of the hourglass TV. The conductive conformal coating also completely fills the waist opening to provide a hermetic seal between an upper opening and a lower opening of the hourglass TV, thus creating the hermetically sealed TV. The combination of the hourglass shape, which provides a narrowing waist, and using the conformal coating process, facilitates the natural accumulation of the conductive conformal coating material in and about the waist opening. Creating hermetically sealed TVs in this manner leads to lower costs, shortened process and plating times, and increased production throughput compared to conventional processes for creating the hermetically sealed TVs in substrates.

### RELATED APPLICATIONS

This application claims the benefit of U.S. Provisional Patent Application Ser. No. 62/109,018 filed Jan. 28, 2015, the disclosure of which is incorporated herein by reference in its entirety.

### FIELD OF THE INVENTION

The present invention relates to three-dimensional (3D) packaging solutions, and in particular to 3D packaging solutions comprising through vias (TVs).

### BACKGROUND OF THE INVENTION

Computing devices such as smartphones have become common in modern society. The prevalence of computing devices may be attributed to the many functions that are enabled within such computing devices. As the computing devices evolve, there is an increased need for high performance active devices that are provided on various substrates along with other semiconductor components to form various types of circuits. These high performance active devices often act as sensors or actuators and are generally referred to as micro-electro-mechanical system (MEMS) devices. MEMS devices are currently being considered in many transportation, medical, wearable, health and wellness, and radio frequency (RF) applications, such as antenna switches, load switches, transmit/receive switches, tuning switches, and the like. Some MEMS devices require a hermetically sealed environment inside a device assembly package to function properly. Conventional methods for creating a device assembly package that is hermetically sealed and contains conductive through vias (TVs) to pass high quality signals has proven to be a challenging task, as illustrated in FIGS. 1A-1C below.

In this regard, FIG. 1A is a schematic diagram illustrating a device assembly 10 manufactured based on a conventional blind via process. According to the conventional blind via process, an intermediate device assembly 10′ (as illustrated in FIG. 1B) is modified to create the device assembly 10. With reference to FIG. 1B, one or more blind vias 12 are first created in a substrate 14 and filled with conductive metal such as copper (Cu). As illustrated in FIG. 1B, the blind vias 12 are “blind,” because they do not extend all the way from a lower surface 16 of the substrate 14 to an upper surface 18 of the substrate 14. Next, the substrate 14 is bonded to a device substrate 20 to create the intermediate device assembly 10′. The blind vias 12 are conductively bonded to runner metal layers 22 disposed on an upper surface 24 of the device substrate 20 via device interconnects 26 (also referred to as via interconnects). The lower surface 16 of the substrate 14 is bonded to the upper surface 24 of the device substrate 20 by a seal ring 28, thus creating a hermetically sealed cavity 30 for a device 32. The substrate 14 has a first height H₁, which may be between three hundred to one thousand micrometers (300 μm to 1000 μm), and perhaps between five hundred to seven hundred micrometers (500 μm to 700 μm).

To modify the device assembly 10 of FIG. 1A to create the intermediate device assembly 10′, the substrate 14 of the intermediate device assembly 10′ is ground down to a background line 34 to create a thinned substrate 14′ having a second height H₂, which is approximately twenty to two hundred micrometers (20 μm to 200 μm) in one embodiment. With reference back to FIG. 1A, after the substrate 14 of FIG. 1B is ground down to create the thinned substrate 14′, the blind vias 12 of FIG. 1B are exposed as TVs 12′ in the thinned substrate 14′ of the device assembly 10. A redistribution layer (RDL) 36 is then disposed on an upper surface 38 of the thinned substrate 14′ to provide conductive coupling for the TVs 12′ in the thinned substrate 14′. One or more soldermasks 40 are then disposed on the upper surface 38 of the thinned substrate 14′ and may overlap with at least a portion of the RDL 36.

FIG. 1C is a schematic diagram illustrating a device assembly 10″ manufactured based on another conventional process involving a carrier substrate 42. Common elements between FIGS. 1A and 1C are shown therein with common element numbers and will not be re-described herein.

One or more TVs 12″ are first created in a substrate 14″. The substrate 14″ is bonded to the carrier substrate 42 via a temporary bond (not shown). The one or more TVs 12″ are then metallized to hermetically seal the one or more TVs 12″. The substrate 14″ is then bonded to the device substrate 20 via the device interconnects 26 disposed between a lower surface 44 of the substrate 14″ and the upper surface 24 of the device substrate 20. Next, the carrier substrate 42 is debonded from the substrate 14″ to expose the temporary bond. The temporary bond is then removed. The RDL 36 and the soldermasks 40 are then disposed on an upper surface 46 of the substrate 14″.

### SUMMARY OF THE INVENTION

Aspects disclosed in the detailed description include hermetically sealed through vias (TVs). In one aspect, to create a hermetically sealed TV in a substrate, an hourglass TV is first created in the substrate. The hourglass TV has a waist opening. A conductive conformal coating covers at least a portion of an interior wall of the hourglass TV. The conductive conformal coating also completely fills the waist opening to provide a hermetic seal between an upper opening and a lower opening of the hourglass TV, thus creating the hermetically sealed TV. The combination of the hourglass shape, which provides a narrowing waist, and using the conformal coating process facilitates the natural accumulation of the conductive conformal coating material in and about the waist opening. This accumulation readily fills the waist opening with the conductive conformal coating material, and thus, hermetically seals an upper cavity of the hermetically sealed TV from a lower cavity, without completely filling the upper and the lower cavities of the hermetically sealed TV. Creating hermetically sealed TVs in this manner leads to lower costs, shortened plating and process times, and increased production throughput compared to conventional processes for creating hermetically sealed TVs in substrates. As a non-limiting example, the substrate may be a glass substrate or a ceramic substrate.

In one aspect of the present disclosure, an apparatus is provided. The apparatus comprises a substrate having at least one hourglass TV. The at least one hourglass TV comprises an hourglass-shaped cross section that extends between an upper opening on a top surface of the substrate and a lower opening on a bottom surface of the substrate. The at least one hourglass TV also comprises an upper cavity that extends between the upper opening and a waist opening. The waist opening is inside the at least one hourglass TV and between the upper opening and the lower opening. The at least one hourglass TV also comprises a lower cavity that extends between the lower opening and the waist opening. The waist opening has a width that is less than a width of the upper opening and a width of the lower opening. The at least one hourglass TV also comprises a conductive conformal coating that covers at least a portion of an interior wall of the hourglass TV and fills the waist opening to provide a hermetic seal between the upper opening and the lower opening.

In another aspect of the present disclosure, a method for creating hermetically sealed TVs in a substrate is provided. The method comprises creating one or more hourglass TVs each extending from a top surface of the substrate to a bottom surface of the substrate. The method also comprises applying an adhesion and seed layer on the top surface of the substrate, the bottom surface of the substrate, and interior walls of the one or more hourglass TVs. The method also comprises creating patterns around the one or more hourglass TVs to create a redistribution layer (RDL) pattern on the top surface and the bottom surface of the substrate. The method also comprises applying a conductive conformal coating to hermetically seal the one or more hourglass TVs.

Those skilled in the art will appreciate the scope of the present invention and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the invention and, together with the description, serve to explain the principles of the invention.

FIG. 1A is a schematic diagram illustrating a device assembly manufactured based on a conventional blind via process;

FIG. 1B is a schematic diagram illustrating an intermediate device assembly for manufacturing the device assembly of FIG. 1A based on the conventional blind via process;

FIG. 1C is a schematic diagram illustrating a device assembly manufactured based on another conventional process involving a carrier substrate;

FIG. 2A is a schematic diagram illustrating an exemplary substrate having at least one hourglass through via (TV);

FIG. 2B is a schematic diagram of at least one hermetically sealed TV created based on the at least one hourglass TV of FIG. 2A;

FIG. 3 is a schematic diagram of an exemplary device assembly;

FIG. 4A is a schematic diagram providing an exemplary illustration of a via formation step for creating the at least one hermetically sealed TV of FIG. 2B;

FIG. 4B is a schematic diagram providing an exemplary illustration of a seed layer formation step for creating the at least one hermetically sealed TV of FIG. 2B;

FIG. 4C is a schematic diagram providing an exemplary illustration of a pattern formation step for creating the at least one hermetically sealed TV of FIG. 2B;

FIG. 4D is a schematic diagram providing an exemplary illustration of a conductive conformal coating step for creating the at least one hermetically sealed TV of FIG. 2B;

FIG. 4E is a schematic diagram providing an exemplary illustration of a pattern removal step for creating the at least one hermetically sealed TV of FIG. 2B;

FIG. 5 is a flowchart of an exemplary hourglass TV formation process according to process steps illustrated in FIGS. 4A-4E;

FIG. 6A is a schematic diagram of an exemplary hourglass TV having a biased waist opening;

FIG. 6B is a schematic diagram of an exemplary hourglass TV formed with non-linear interior walls;

FIG. 6C is a schematic diagram of another exemplary hourglass TV formed with non-linear interior walls;

FIG. 6D is a schematic diagram of an exemplary hourglass TV having an upper rim concave and a lower rim concave;

FIG. 6E is a schematic diagram of an exemplary hourglass TV having an elongated waist; and

FIG. 6F is a schematic diagram of an exemplary hourglass TV having asymmetrical upper cavity and lower cavity.

### DETAILED DESCRIPTION OF THE PREFERRED EMBODIMENTS

The embodiments set forth below represent the necessary information to enable those skilled in the art to practice the invention and illustrate the best mode of practicing the invention. Upon reading the following description in light of the accompanying drawing figures, those skilled in the art will understand the concepts of the invention and will recognize applications of these concepts not particularly addressed herein. It should be understood that these concepts and applications fall within the scope of the disclosure and the accompanying claims.

Aspects disclosed in the detailed description include hermetically sealed through vias (TVs). In one aspect, to create a hermetically sealed TV in a substrate, an hourglass TV is first created in the substrate. The hourglass TV has a waist opening. A conductive conformal coating covers at least a portion of an interior wall of the hourglass TV. The conductive conformal coating also completely fills the waist opening to provide a hermetic seal between an upper opening and a lower opening of the hourglass TV, thus creating the hermetically sealed TV. The combination of the hourglass shape, which provides a narrowing waist, and using the conformal coating process facilitates the natural accumulation of the conductive conformal coating material in and about the waist opening. This accumulation readily fills the waist opening with the conductive conformal coating material, and thus, hermetically seals an upper cavity of the hermetically sealed TV from a lower cavity, without completely filling the upper and the lower cavities of the hermetically sealed TV. Creating hermetically sealed TVs in this manner leads to lower costs, shortened plating and process times, and increased production throughput compared to conventional processes for creating hermetically sealed TVs in substrates. As a non-limiting example, the substrate may be a glass substrate or a ceramic substrate.

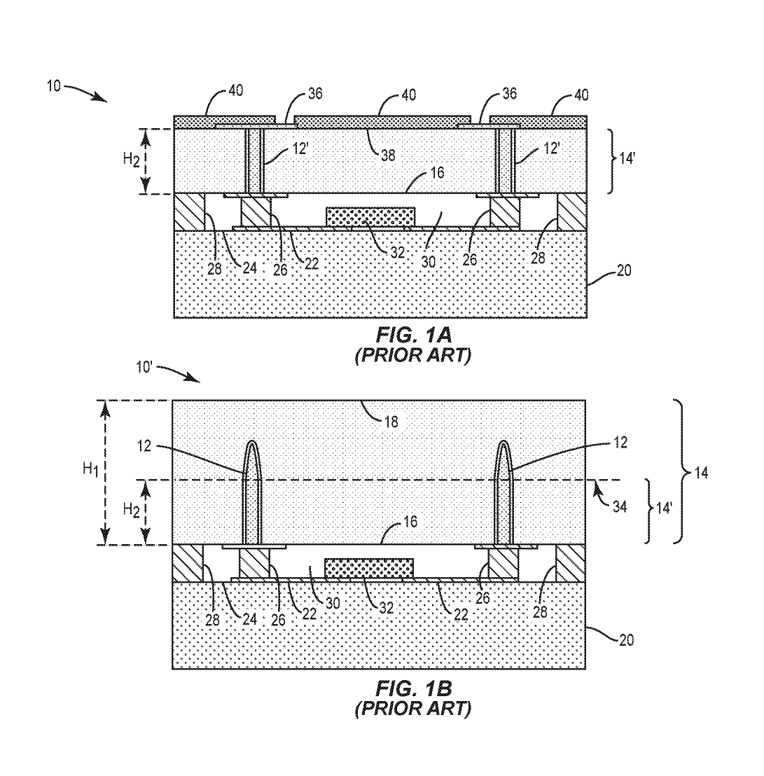

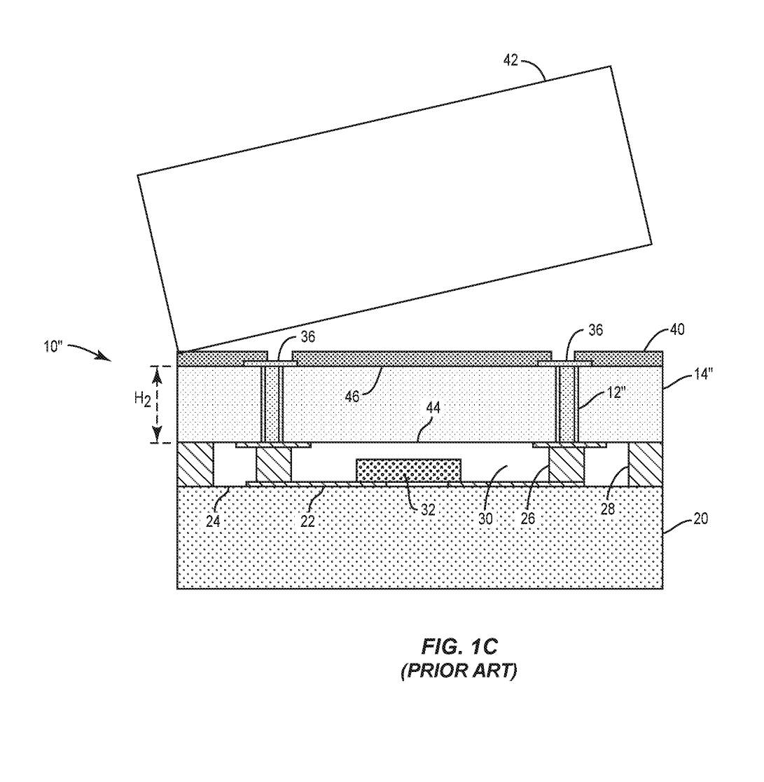

Both the conventional blind via process of FIG. 1A and the conventional process involving the carrier substrate 42 of FIG. 1B have obvious shortcomings. Issues associated with the conventional blind via process of FIG. 1A include higher manufacturing costs associated with filling the blind vias 12 and having the substrate 14 ground down after the device assembly 10 is manufactured. Issues associated with the conventional process of FIG. 1B are that the process of removing the carrier substrate 42 after manufacturing the device assembly 10″ is both complicated and costly. As such, it may be desired to create hermetically sealed TVs in a substrate with reduced costs and complexity.

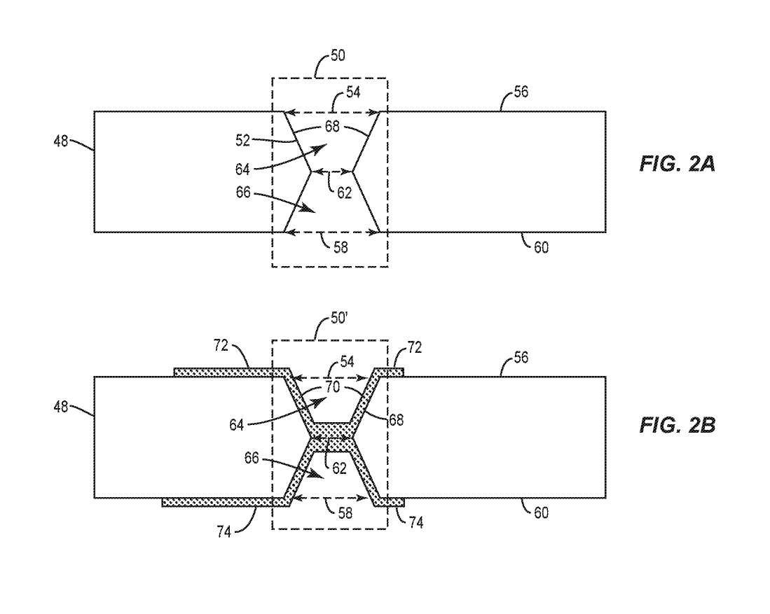

In this regard, FIG. 2A is a schematic diagram illustrating an exemplary substrate 48 having at least one hourglass TV 50. In a non-limiting example, the substrate may be a glass substrate or a ceramic substrate. The hourglass TV 50 includes an hourglass-shaped cross section 52 that extends between an upper opening 54 on a top surface 56 of the substrate 48 and a lower opening 58 on a bottom surface 60 of the substrate 48. The hourglass TV 50 also has a waist opening 62 located between the upper opening 54 and the lower opening 58. The waist opening 62 separates the hourglass-shaped cross section 52 into an upper cavity 64 and a lower cavity 66. The upper cavity 64 extends between the upper opening 54 and the waist opening 62. The lower cavity 66 extends between the waist opening 62 and the lower opening 58. The hourglass-shaped cross section 52 has an interior wall 68 that may be linear or curved, for example.

Subsequently, the hourglass-shaped cross section 52 may be hermetically sealed with conformal metallization. In this regard, FIG. 2B is a schematic diagram of the hourglass TV 50 of FIG. 2A that is hermetically sealed with conformal metallization to create a hermetically sealed TV 50′. A conductive conformal coating 70 is applied to cover at least a portion of the interior wall 68 and to fill the waist opening 62, thus providing a hermetic seal between the upper opening 54 and the lower opening 58. The conductive conformal coating 70 also completely fills the waist opening 62 to provide a hermetic seal between the upper opening 54 and the lower opening 58 of the hourglass TV 50, thus creating the hermetically sealed TV 50′. The combination of the hourglass shape, which provides a narrowing waist like the waist opening 62, and using the conformal coating process facilitates the natural accumulation of the conductive conformal coating material in and about the waist opening 62. This accumulation readily fills the waist opening 62 with the conductive conformal coating material, and thus, hermetically seals the upper cavity 64 of the hermetically sealed TV 50′ from the lower cavity 66, without completely filling the upper cavity 64 and the lower cavity 66 of the hermetically sealed TV 50′. In a non-limiting example, the upper cavity 64 and the lower cavity 66 may be less than seventy-five percent (75%) or less than fifty percent (50%) filled by the conductive conformal coating material. Additionally, an upper conductive trace 72 may be applied around the upper opening 54 on the top surface 56 of the substrate 48. Likewise, a lower conductive trace 74 may be applied around the lower opening 58 on the bottom surface 60 of the substrate 48. In this regard, the conductive conformal coating 70 extends between the upper conductive trace 72 and the lower conductive trace 74 to provide electrical contact between the upper conductive trace 72 and the lower conductive trace 74.

The hermetically sealed TV 50′ created by a combination of creating the hourglass TV 50 in the substrate 48 and applying conformal metallization over the hourglass-shaped cross section 52 has several advantages over the conventional blind via process of FIG. 1A and the conventional process of FIG. 1B. In one aspect, it is possible to create the hermetically sealed TV 50′ in the substrate 48 and apply the conductive conformal coating 70 prior to bonding the substrate 48 to a device substrate. In another aspect, it is also possible to create the hermetically sealed TV 50′ in the substrate 48 and bond the substrate 48 to another substrate before applying the conductive conformal coating 70. In both aspects, the hermetically sealed TV 50′ created in the substrate 48 by the combination of hourglass shape and utilization of conformal metallization can lead to reduced costs, shortened plating time, and increased throughput in production.

The substrate 48 can be bonded to another substrate, such as a device substrate, to create a device assembly. In this regard, FIG. 3 is a schematic diagram of an exemplary device assembly 76 that includes the substrate 48 of FIG. 2B and a device substrate 78. Common elements between FIGS. 2B and 3 are shown therein with common element numbers and will not be re-described herein.

The device assembly 76 includes the device substrate 78. The device substrate 78 has an upper surface 80 and a lower surface 82. A conductive sealing ring 84 is disposed between the bottom surface 60 of the substrate 48 and the upper surface 80 of the device substrate 78 to create a substantially hermetically sealed cavity 86 for at least one active device 88. In a non-limiting example, the at least one active device 88 may be provided on the upper surface 80 of the device substrate 78 or on the bottom surface 60 of the substrate 48. The at least one active device 88 may be electrically coupled to the hermetically sealed TV 50′ in the substrate 48 via runner metal layer 90, via interconnect 92, and the lower conductive trace 74.

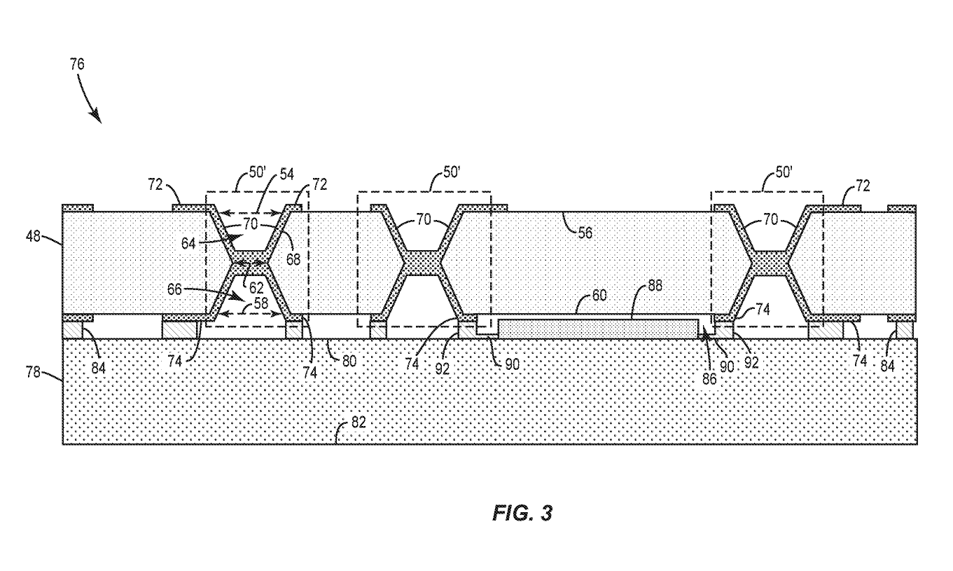

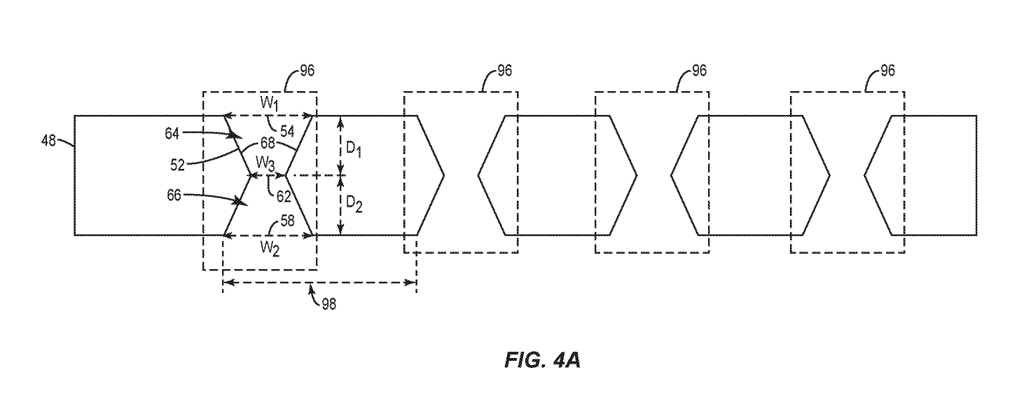

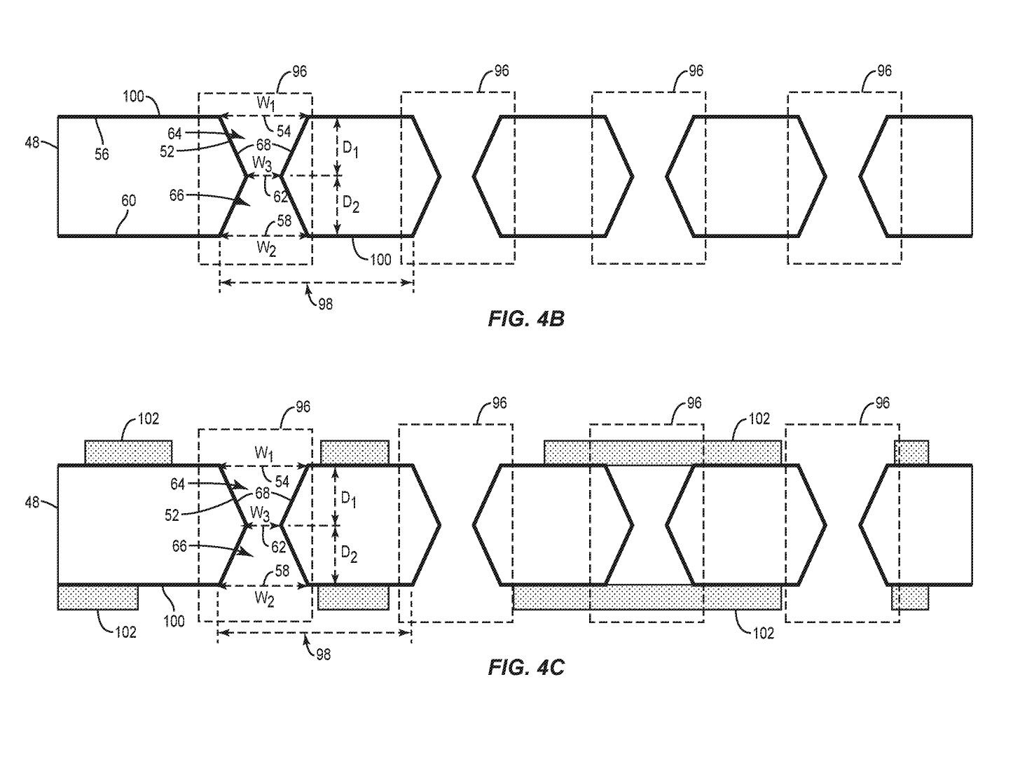

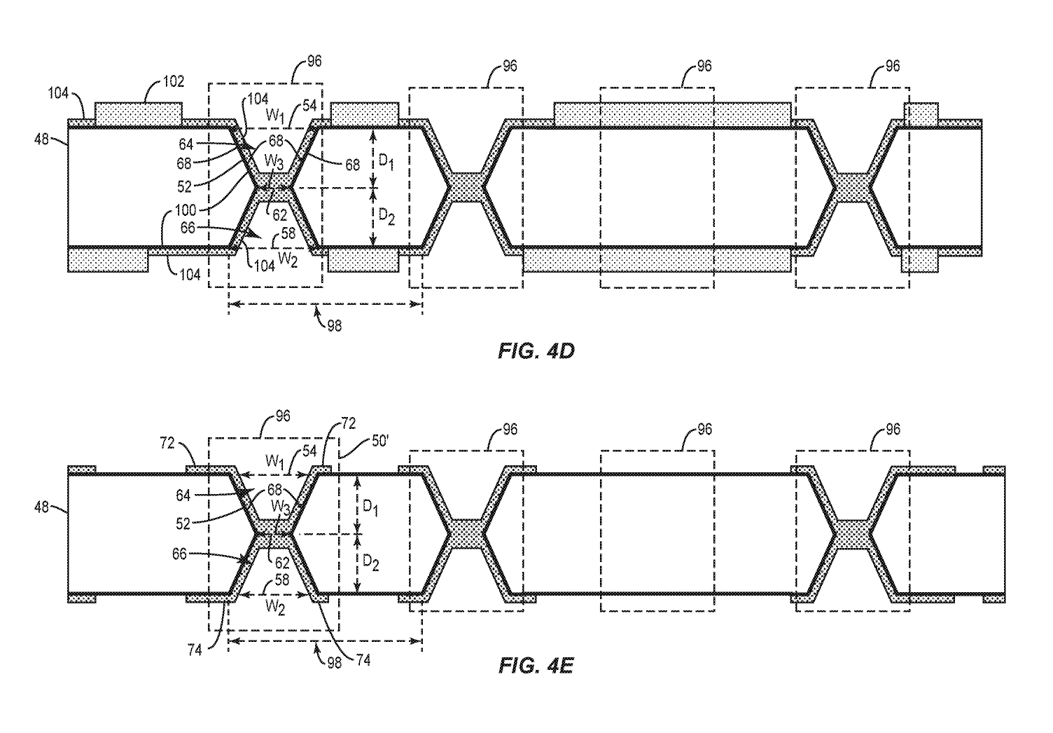

To further illustrate a step-by-step process for creating the hermetically sealed TV 50′ in the substrate 48, FIGS. 4A-4E are provided and discussed next. Common elements between FIGS. 2A-2B, 3, and 4A-4E are shown therein with common element numbers and will not be re-described herein.

FIG. 4A is a schematic diagram providing an exemplary illustration of a via formation step (also referred to herein as process step 1) for creating the hermetically sealed TV 50′ in the substrate 48 of FIG. 2B. In a non-limiting example, thickness of the substrate 48 may be between twenty to three hundred micrometers (20 μm to 300 μm). One or more hourglass TVs 96 are created and distributed according to a pitch distance 98 in the substrate 48. In a non-limiting example, the pitch distance 98 may be greater than or equal to the diameter of the hourglass TVs 96.

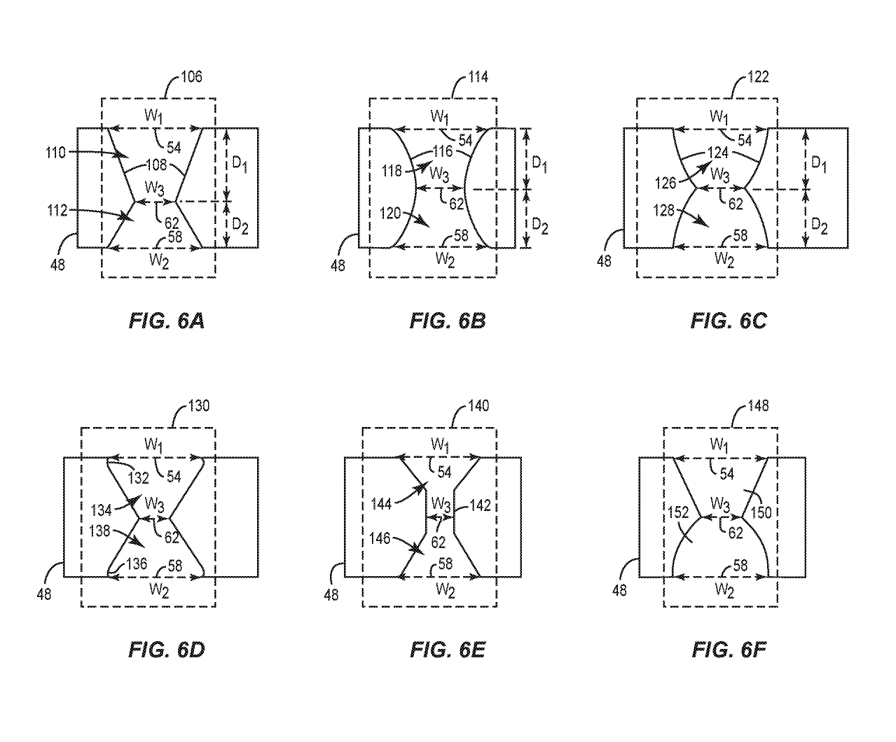

Each of the one or more hourglass TVs 96 has the hourglass-shaped cross section 52 that includes the upper opening 54, the lower opening 58, and the waist opening 62. The upper opening 54, the lower opening 58, and the waist opening 62 have respective widths W₁, W₂, and W₃. In a non-limiting example, W₁ and W₂ may each be between twenty to sixty micrometers (20 μm to 60 μm), and W₃ may be approximately ten to thirty micrometers (≈10 μm to 30 μm). While W₁ may be greater than W₂, less than W₂, or substantially equal to W₂, W₃ is always less than both W₁ and W₂. In another non-limiting example, the pitch distance 98 may also be determined to be twice the larger width between W₁ and W₂. For example, the pitch distance 98 may be equal to 2×W₁ when W₁≧W₂ or 2×W₂ when W₁<W₂. The waist opening 62 has a vertical distance D₁ from the upper opening 54 and a vertical distance D₂ from the lower opening 58. D₁ may be greater than D₂, less than D₂, or substantially equal to D₂ regardless whether W₁ is greater than W₂, less than W₂, or equal to W₂. In this regard, D₁ may be greater than D₂, less than D₂, or substantially equal to D₂ when W₁≧W₂ or when W₁<W₂. In one non-limiting example, the upper cavity 64 and the lower cavity 66 may be conical-shaped cavities. However, the upper cavity 64 and the lower cavity 66 may take on other shapes, as will be described further below in FIGS. 6A-6F.

FIG. 4B is a schematic diagram providing an exemplary illustration of a seed layer formation step (process step 2) for creating the hermetically sealed TV 50′ in the substrate 48 of FIG. 2B. During the seed layer formation step, an adhesion and seed layer 100 is applied on the top surface 56 and the bottom surface 60 of the substrate 48. The adhesion and seed layer 100 is further applied to the interior walls 68 of the one or more hourglass TVs 96. In a non-limiting example, the adhesion and seed layer 100 may be copper (Cu).

FIG. 4C is a schematic diagram providing an exemplary illustration of a pattern formation step (process step 3) for creating the hermetically sealed TV 50′ in the substrate 48 of FIG. 2B. During the pattern formation step, (film, stenciled, or like) patterns 102 are created around the one or more hourglass TVs 96 and on top of the adhesion and seed layer 100. In a non-limiting example, the patterns 102 are created by resist. In another non-limiting example, space of the patterns 102 may be greater than five micrometers (>5 μm).

FIG. 4D is a schematic diagram providing an exemplary illustration of a conductive conformal coating step (process step 4) for more naturally creating the hermetically sealed TV 50′ in the substrate 48 of FIG. 2B. During the conductive conformal coating step, a conductive conformal coating 104 is formed on the interior wall 68 of the hourglass TVs 96 to hermetically seal the one or more hourglass TVs 96. The hourglass-shape of the hourglass TVs 96 makes the conductive conformal coating 104 accumulate at the narrowing portion, or waist, of the hourglass TVs 96, creating a hermetic seal between the top and bottom portions of the hourglass TVs 96. In a non-limiting example, the conductive conformal coating 104 may be formed by Cu or gold (Au) and has a thickness of between 3 to 10 micrometers (3 μm to 10 μm).

FIG. 4E is a schematic diagram providing an exemplary illustration of a pattern removal step (process step 5) for creating the hermetically sealed TV 50′ in the substrate 48 of FIG. 2B. During the pattern removal step, the patterns 102 are removed. At this point, the hermetically sealed TV 50′ is created. Notably, the upper conductive trace 72 and the lower conductive trace 74 may be formed around the upper opening 54 and the lower opening 58 of the hourglass TV 50, respectively. Subsequently, the substrate 48 is bonded to the device substrate 78 (not shown) of FIG. 3 by the conductive sealing ring 84 (not shown) to create the device assembly 76 (not shown).

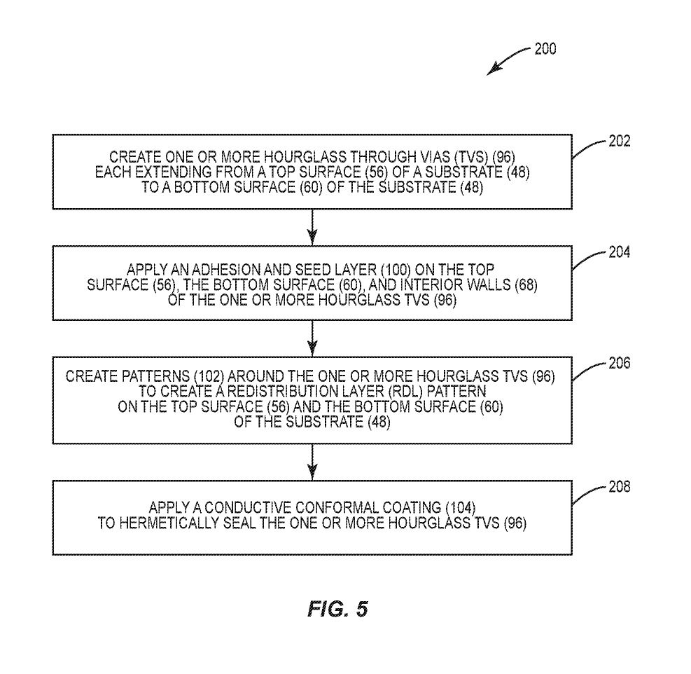

FIG. 5 is a flowchart of an exemplary TV formation process 200 according to process steps illustrated in FIGS. 4A-4E. According to the TV formation process 200, the one or more hourglass TVs 96 are created and extend from the top surface 56 of the substrate 48 to the bottom surface 60 of the substrate 48 (block 202). The adhesion and seed layer 100 is applied on the top surface 56, the bottom surface 60, and the interior walls 68 of the one or more hourglass TVs 96 (block 204). Next, the patterns 102 may be created around the one or more hourglass TVs 96 to create a redistribution layer (RDL) pattern on the top surface 56 and the bottom surface 60 of the substrate 48 (block 206). Then, a conductive conformal coating 104 is applied to hermetically seal the one or more hourglass TVs 96 (block 208). The patterns 102 are then removed from the top surface 56 and the bottom surface 60 of the substrate 48. In case the patterns 102 have not been created prior to applying conformal coating to the one or more hourglass TVs 96, it may be necessary to perform over-burden removal before creating the RDL pattern on both the top surface 56 and the bottom surface 60 of the substrate 48. Finally, the substrate 48 is bound to the device substrate 78 to create the device assembly 76.

The one or more hourglass TVs 96 in FIG. 4A may employ a variety of cavity shapes, as illustrated in FIGS. 6A-6F and still maintain their hourglass shape. It shall be appreciated that FIGS. 6A-6F are provided to facilitate illustration and, thus, shall not be considered as being restrictive. Common elements between FIGS. 4A and 6A-6F are shown therein with common element numbers and will not be re-described herein.

FIG. 6A is a schematic diagram of an exemplary hourglass TV 106 in which the waist opening 62 is biased and interior walls 108 of an upper cavity 110 and a lower cavity 112 are substantially linear. The waist opening 62 is bottom-biased when D₁>D₂ and top-biased when D₁<D₂. In a non-limiting example, when D₁ differs from D₂, it is preferable that a differential between D₁ and D₂ is no more than ten percent (10%) of the thickness of the substrate 48. In the non-limiting example illustrated in FIG. 6A, the waist opening 62 is bottom-biased (e.g., D₁>D₂). In certain embodiments, the ratio of D₁ to D₂ may be two to one (2:1) or greater.

FIG. 6B is a schematic diagram of an exemplary hourglass TV 114 wherein interior walls 116 of an upper cavity 118 and a lower cavity 120 are substantially non-linear and take on a convex shape within each of the upper and lower cavities 118, 120.

FIG. 6C is a schematic diagram of an exemplary hourglass TV 122 wherein the interior walls 124 of an upper cavity 126 and a lower cavity 128 are substantially non-linear and take on a concave shape within each of the upper and lower cavities 126, 128.

FIG. 6D is a schematic diagram of an exemplary hourglass TV 130 having a concave upper rim 132 at or near an uppermost portion of an upper cavity 134 and a concave lower rim 136 at or near a lowermost portion of a lower cavity 138.

FIG. 6E is a schematic diagram of an exemplary hourglass TV 140 having an elongated waist 142. Although the width of the elongated waist 142 is uniform, it need not be. The hourglass TV 140 has an upper cavity 144 and a lower cavity 146.

FIG. 6F is a schematic diagram of an exemplary TV 148 having asymmetrical cavity shapes for an upper cavity 150 and a lower cavity 152. Virtually any combination of shapes and sizes are envisioned so long as the overall relationship between the upper cavity 64 and the lower cavity 66 of FIG. 2A are joined at a waist and form an hourglass shape.

Those skilled in the art will recognize improvements and modifications to the preferred embodiments of the present invention. All such improvements and modifications are considered within the scope of the concepts disclosed herein and the claims that follow.

What is claimed is:

1. An apparatus comprising a substrate having at least one hourglass through via (TV) comprising:
an hourglass-shaped cross section that extends between an upper opening on a top surface of the substrate and a lower opening on a bottom surface of the substrate;
an upper cavity that extends between the upper opening and a waist opening, which is inside the at least one hourglass TV and between the upper opening and the lower opening;
a lower cavity that extends between the lower opening and the waist opening, wherein the waist opening has a width that is less than a width of the upper opening and a width of the lower opening; and
a conductive conformal coating that covers at least a portion of an interior wall of the at least one hourglass TV and fills the waist opening to provide a hermetic seal between the upper opening and the lower opening.

2. The apparatus of claim 1 wherein the upper cavity and the lower cavity are conical-shaped cavities.

3. The apparatus of claim 1 wherein the width of the upper opening is greater than the width of the lower opening.

4. The apparatus of claim 3 wherein a vertical distance between the upper opening and the waist opening is substantially equal to a vertical distance between the lower opening and the waist opening.

5. The apparatus of claim 3 wherein a vertical distance between the upper opening and the waist opening is less than a vertical distance between the lower opening and the waist opening.

6. The apparatus of claim 1 wherein the width of the upper opening is less than the width of the lower opening.

7. The apparatus of claim 6 wherein a vertical distance between the upper opening and the waist opening is substantially equal to a vertical distance between the lower opening and the waist opening.

8. The apparatus of claim 6 wherein a vertical distance between the upper opening and the waist opening is less than a vertical distance between the lower opening and the waist opening.

9. The apparatus of claim 1 wherein the width of the upper opening is substantially equal to the width of the lower opening.

10. The apparatus of claim 9 wherein a vertical distance between the upper opening and the waist opening is substantially equal to a vertical distance between the lower opening and the waist opening.

11. The apparatus of claim 9 wherein a vertical distance between the upper opening and the waist opening is less than a vertical distance between the lower opening and the waist opening.

12. The apparatus of claim 1 further comprising:
an upper conductive trace on the top surface of the substrate;
a lower conductive trace on the bottom surface of the substrate; and
the conductive conformal coating extends between the upper conductive trace and the lower conductive trace to provide electrical contact between the upper conductive trace and the lower conductive trace.

13. The apparatus of claim 1 provided in a device assembly that comprises:
a device substrate comprising an upper surface and a lower surface;
at least one active device provided on the bottom surface of the substrate and electrically coupled to the at least one hourglass TV in the substrate; and
a conductive sealing ring disposed between the bottom surface of the substrate and the upper surface of the device substrate, the conductive sealing ring encapsulating the at least one active device to define a substantially hermetically sealed cavity.

14. The apparatus of claim 1 wherein the substrate is comprised of a glass substrate.

15. The apparatus of claim 1 wherein the substrate is comprised of a ceramic substrate.

16. The apparatus of claim 1 wherein the upper cavity and the lower cavity are not filled by the conductive conformal coating that covers at least a portion of an interior wall of the at least one hourglass TV.

17. The apparatus of claim 16 wherein the upper cavity and the lower cavity are less than seventy-five percent (75%) filled by the conductive conformal coating.

18. A method for creating hermetically sealed through vias (TVs) in a substrate, comprising:
creating one or more hourglass TVs each extending from a top surface of the substrate to a bottom surface of the substrate;
applying an adhesion and seed layer on the top surface of the substrate, the bottom surface of the substrate, and interior walls of the one or more hourglass TVs;
creating patterns around the one or more hourglass TVs to create a redistribution layer (RDL) pattern on the top surface and the bottom surface of the substrate; and
applying a conductive conformal coating to hermetically seal the one or more hourglass TVs.

19. The method of claim 18 further comprising:
patterning around the one or more hourglass TVs with a resist to create the redistribution layer (RDL) pattern on the top surface and the bottom surface of the substrate prior to applying the conductive conformal coating to the one or more hourglass TVs; and
removing the resist from the top surface and the bottom surface of the substrate after applying the conductive conformal coating to the one or more hourglass TVs.

20. The method of claim 18 further comprising providing at least one active device to the bottom surface of the substrate.

21. The method of claim 20 further comprising encapsulating the at least one active device by a conductive sealing ring disposed between the bottom surface of the substrate and an upper surface of a device substrate to create a substantially hermetically sealed cavity.
